(19) United States
(12) Patent Application Publication
(10) Pub. No.: US 2019/0123165 A1
(43) Pub. Date: Apr. 25, 2019

(54) SEMICONDUCTOR DEVICE AND CMOS TRANSISTOR

(71) Applicant: TOKYO ELECTRON LIMITED, Tokyo (JP)

(72) Inventors: Koji AKIYAMA, Nirasaki City (JP); Hajime NAKABAYASHI, Tokyo (JP); Kazuki HASHIMOTO, Nirasaki City (JP); Sara OTSUKI, Nirasaki City (JP)

(21) Appl. No.: 16/169,233

(22) Filed: Oct. 24, 2018

(30) Foreign Application Priority Data
Oct. 24, 2017 (JP) 2017-205069

(51) Int. Cl. H01L 29/51; H01L 29/49; H01L 29/12; H01L 27/092

(52) U.S. Cl. CPC H01L 29/511; H01L 29/4966; H01L 27/0924; H01L 29/122; H01L 29/517

(57) ABSTRACT

There is provided a semiconductor device. The semiconductor device includes a first electrode made of a metal, a first semiconductor, a first insulating film configured to be provided between the first electrode and the first semiconductor and to be made of an insulating transition metal oxide and an intermediate film configured to be provided between the first electrode and the first insulating film. A lower end of a conduction band of the intermediate film is lower than a Fermi level of the metal constituting the first electrode.

### CROSS-REFERENCE TO RELATED APPLICATION

This application claims the benefit of Japanese Patent Application No. 2017-205069, filed on Oct. 24, 2017, in the Japan Patent Office, the disclosure of which is incorporated herein in its entirety by reference.

### TECHNICAL FIELD

The present disclosure relates to a semiconductor device and a CMOS transistor.

### BACKGROUND

A work function of titanium nitride (TiN), which is one of the typical gate electrode materials of a transistor as a semiconductor device, has a dependence on crystal plane orientation, so that there is a difference of 0.2 eV between the work functions of TiN of (110) plane and (111) plane. In the case where a silicon (Si) channel of the FinFET of a three-dimensional (3D) transistor used in a fine semiconductor circuit is covered with a TiN gate electrode, local fluctuation of a potential on the Si channel occurs due to a difference in the work function for each metal crystal grain. This causes variations in the characteristics (for example, a value of a threshold voltage Vth) between semiconductor devices.

In order to solve this problem, forming a gate electrode with an amorphous metal has been studied. Tantalum silicon nitride (TaSiN) is known as a representative material of amorphous metal applicable to the gate electrode. By using the amorphous metal for the gate electrode, the variation in the threshold voltage Vth due to the crystal plane orientation of the work function is reduced.

### SUMMARY

The threshold voltage Vth of the transistor is influenced by a plurality of factors such as Short Channel Effect (SCE), Drain Induced Barrier Lowering (DIBL), body effect, and the like. However, the work function of the material used for the gate electrode is a main factor for determining the threshold voltage Vth. For example, as shown in FIG. 1, it is estimated that the value of the work function required for the gate electrode of the transistor to be miniaturized is 4.9 to 5.1 eV for a p-type transistor and 4.3 to 4.5 eV for an n-type transistor. The variation in the work function of the electrode is directly reflected in the variation in the threshold voltage Vth of the transistor.

The variation in the threshold voltage Vth greatly affects the characteristics of the semiconductor device, and the extent to which the influence of the characteristics can be neglected is, for example, about 10 mV as shown in FIG. 2. In the manufacturing process of a transistor, the threshold voltage Vth has been conventionally adjusted by impurity ion implantation. However, due to miniaturization of transistors in recent years, statistical variations in doped impurity concentrations have been revealed, and the statistical variations themselves have caused the variation in the threshold voltage Vth. Therefore, impurity doping into the channel and body of the transistor tends to be avoided. For this reason, in order to fabricate a transistor having the threshold voltage Vth designed for various uses such as high output, low output, input and output, and the like, it is necessary to select different work functions for the gate electrode.

However, the metal material having a high work function necessary especially for a p-type transistor (for example, Pt or the like) generally has a problem of poor processability. For example, as shown in FIGS. 3 and 4, the value of the work function may be changed by fusing a plurality of metals, but since the value of the work function of an alloy has no additivity, it is difficult to convert the value of the work function into the designed value by the fusion of the plurality of metals. Accordingly, as the miniaturization of the semiconductor progresses, it is becoming difficult to prepare transistors having various threshold voltages Vth necessary for circuit formation.

According to one embodiment of the present disclosure, there is provided a semiconductor device including: a first electrode made of a metal; a first semiconductor; a first insulating film configured to be provided between the first electrode and the first semiconductor and to be made of an insulating transition metal oxide; and an intermediate film configured to be provided between the first electrode and the first insulating film, wherein a lower end of a conduction band of the intermediate film is lower than a Fermi level of the metal constituting the first electrode.

According to another embodiment of the present disclosure, there is provided a CMOS transistor including: an n-type MOS transistor including a second electrode, a second insulating film, and a second semiconductor as a gate stack structure; and a p-type MOS transistor including the semiconductor device as a gate stack structure.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an example of a work function of a gate electrode necessary for a high performance logic transistor of each generation.

FIG. 2 is a diagram showing an example of the influence of variations in a threshold voltage Vth on transistor characteristics.

FIG. 3 is a diagram showing a work function of each metal material.

FIG. 4 is a diagram showing an example of a result of adjustment of a work function value by a binary alloy system.

FIG. 5 is a conceptual diagram showing an example of forming a pseudo metal electrode with a quantum well.

FIGS. 6A and 6B are schematic diagrams showing an example of quantum wells of a Metal Insulator Metal (MIM) structure and an Insulator Metal Insulator (IMI) structure.

FIG. 7 is a diagram showing an example of a candidate of a quantum well material in an MIM structure.

FIGS. 8A and 8B are diagrams showing an example of a semiconductor device according to an embodiment.

FIG. 9 is a diagram showing another example of a semiconductor device.

FIGS. 10A to 10C are diagrams showing an example of adjustment of a work function by a quantum well diameter of an insulator.

FIG. 11 is a diagram showing an example of the relationship between the quantum well diameter and the Fermi level of an insulator.

FIGS. 12A to 12C are diagrams showing an example of modulation of a work function by a material of a metal electrode and a quantum well diameter.

FIG. 13 is a diagram showing an example of a change in a work function of a quantum well structure with respect to a film thickness of an intermediate film in a case where TiN is used as an electrode, V₂O₅ is used as an intermediate film, and HfO₂ is used as an insulating film.

FIG. 14 is a diagram showing an example of a change in a threshold voltage Vth of a semiconductor device with respect to a film thickness of an intermediate film in a case where TiN is used as an electrode, V₂O₅ is used as an intermediate film, and HfO₂ is used as an insulating film.

FIG. 15 is a diagram illustrating an example of an experimental result of a leakage current.

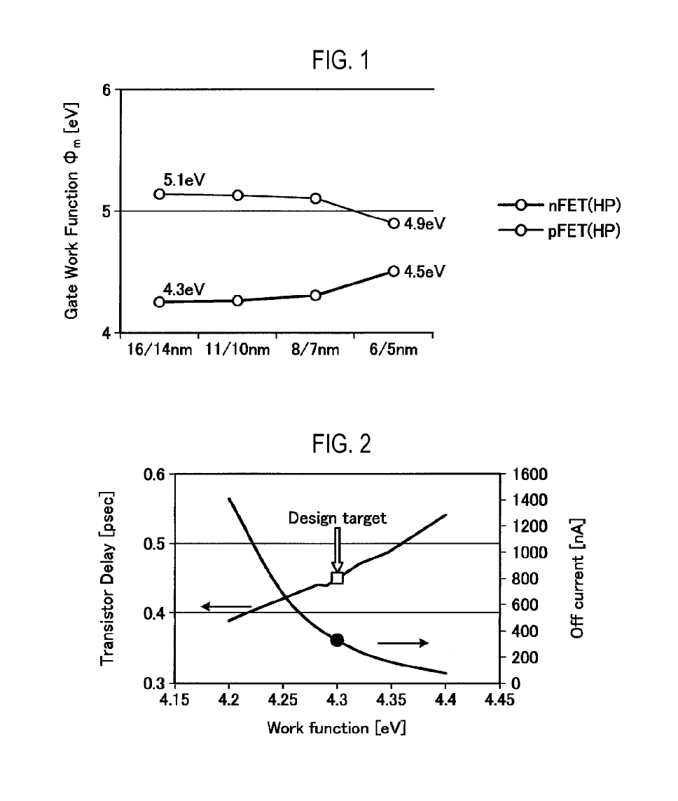

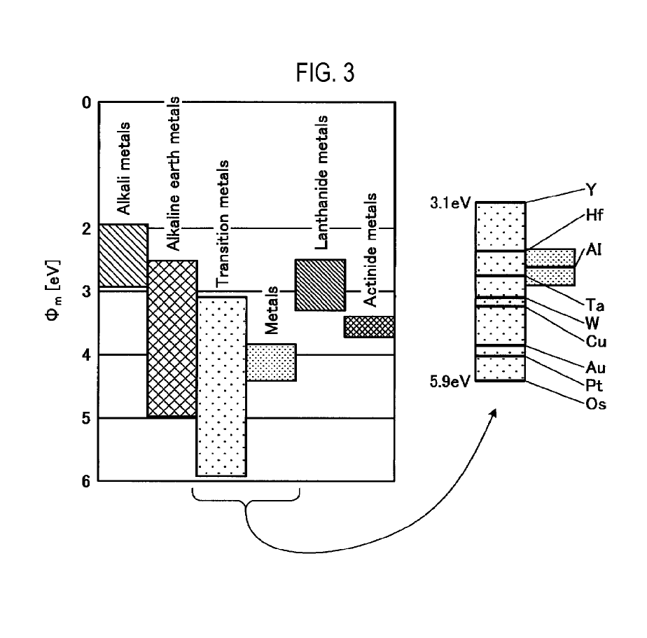

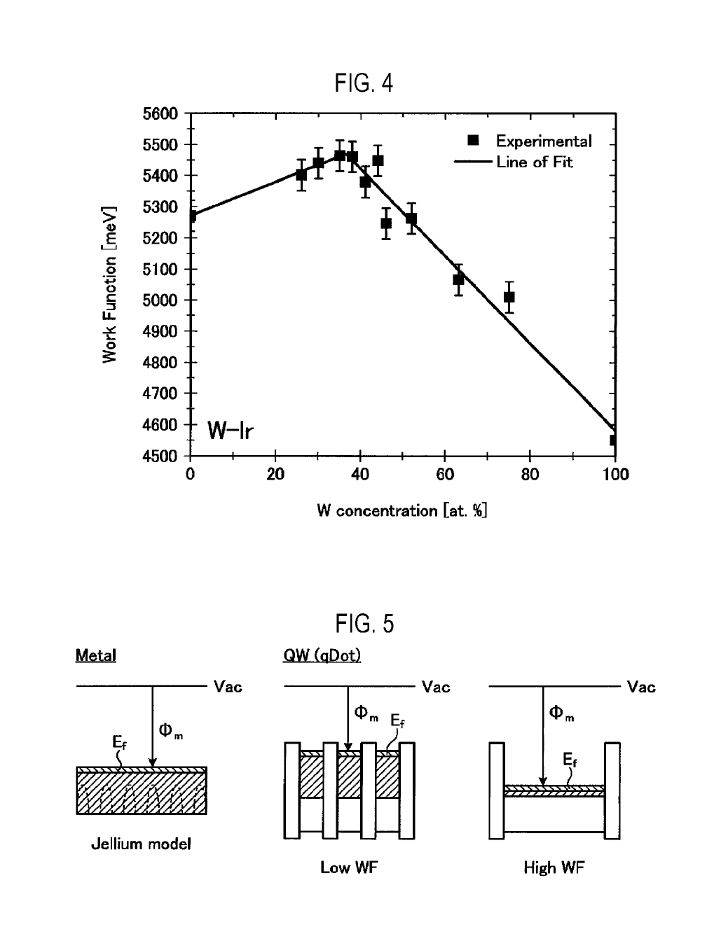

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

For example, in one embodiment, a disclosed semiconductor device includes a first electrode, a first semiconductor, a first insulating film, and an intermediate film. The first electrode is made of a metal. The first insulating film is provided between the first electrode and the first semiconductor and is made of an insulating transition metal oxide. The intermediate film is provided between the first electrode and the first insulating film. In addition, the lower end of a conduction band of the intermediate film is lower than the Fermi level of a metal constituting the first electrode.

In addition, in one embodiment of the disclosed semiconductor device, the thickness of the intermediate film may be 1 nm or less.

Further, in one embodiment of the disclosed semiconductor device, the transition metal oxide constituting the first insulating film may be an oxide selected from an oxide group including hafnium oxide (HfO₂), zirconia (ZrO₂), aluminum oxide (A1₂O₃), yttrium oxide (Y₂O₃), cesium oxide (CeO₂), lanthanum oxide (La₂O₃), gadolinium oxide (Gd₂O₃), tantalum pentoxide (Ta₂O₅) and niobium pentoxide (Nb₂O₅), a complex oxide composed of a plurality of oxides selected from the oxide group, a silicate, or a laminated film composed of a plurality of oxides selected from the oxide group. Further, the intermediate film may contain at least one of vanadium pentoxide (V₂O₅) and molybdenum oxide (MoO₃).

Further, in one embodiment, a disclosed CMOS transistor includes an n-type MOS transistor having a second electrode, a second insulating film, and a second semiconductor, as a gate stack structure, and a p-type MOS transistor having the semiconductor device, as a gate stack structure.

Hereinafter, embodiments of the disclosed semiconductor device and the CMOS transistor will be described in detail with reference to the drawings. It should be noted that the disclosed semiconductor device and CMOS transistor are not limited by the present embodiment.

### Quantum Well Structure

FIG. 5 is a conceptual diagram showing an example of forming a pseudo metal electrode with a quantum well. In the quantum well structure, a quantized subband structure depending on the size of a quantum well is formed. The Fermi energy of the quantum well structure is determined by the energy of the upper end of an electron-occupied subband.

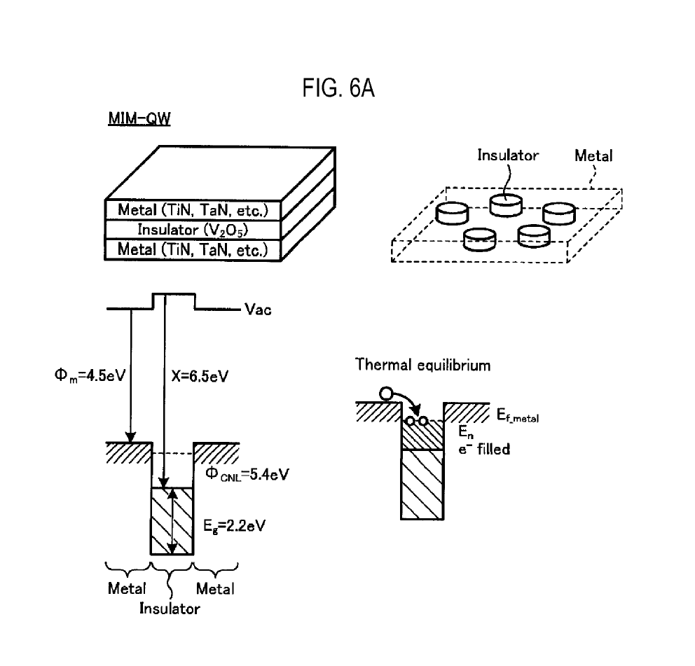

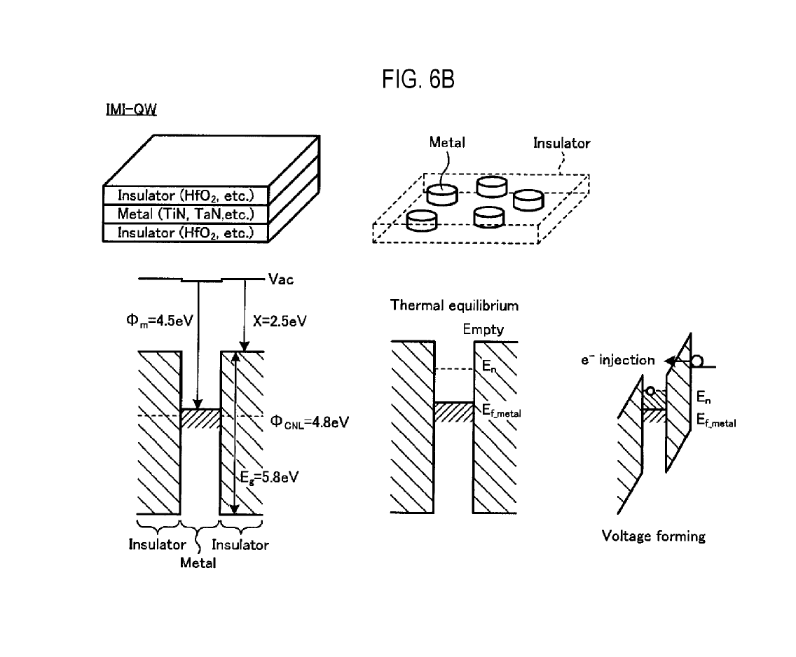

Usually, the quantum well is formed as an Insulator Metal Insulator (IMI) structure in which the metal of a well portion is surrounded by an insulator, as shown in FIG. 5. However, in the case of an insulator having a larger electron affinity than the work function of the metal, a pseudo metal structure in which electrons are spontaneously accumulated in a well may be formed, for example, by a Metal Insulator Metal (MIM) structure, as shown in FIGS. 6A and 6B. FIGS. 6A and 6B are schematic diagrams showing an example of quantum wells of an MIM structure and an IMI structure. FIG. 6A is a schematic diagram illustrating an example of the quantum well of the MIM structure, and FIG. 6B is a schematic diagram illustrating an example of the quantum well of the IMI structure.

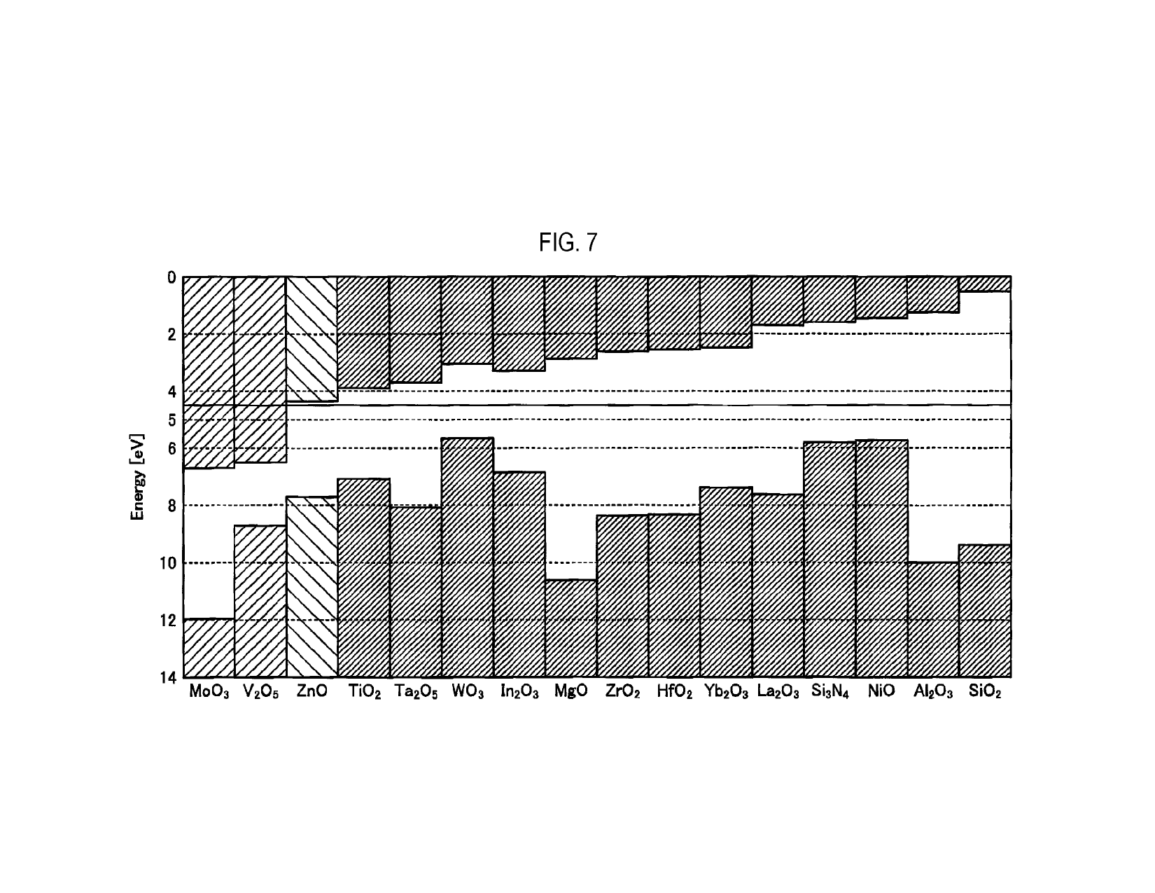

Many metals frequently used as the electrode material of the semiconductor device have work functions of, for example, around 4.5 eV. However, MoO₃ and V₂O₅ are insulators exhibiting an extremely large electron affinity of around 6.5 eV, for example, as shown in FIG. 7. FIG. 7 is a diagram showing an example of a candidate of the quantum well material in the MIM structure.

By combining a thin film of MoO₃ or V₂O₅ with a metal electrode such as TiN or the like, an adjacent metal electrode serves as an electron supply source, so that the subband of the quantum well of the insulating film is naturally electron-occupied in a thermal equilibrium state. Then, a pseudo metal electrode having the quantum well of the MIM structure is formed. In addition, the quantum well structure functioning as the pseudo metal electrode may also be realized by a Metal Insulator Insulator (MII) structure in which a metal electrode serving as an electron supply source exists only on one side. The pseudo metal electrode having the MII structure may be formed by forming a laminated structure in which MoO₃, V₂O₅, or the like is sandwiched between an insulating material having a smaller electron affinity than a material such as MoO₃ or V₂O₅ and a metal electrode.

### Structure of a Semiconductor Device 10

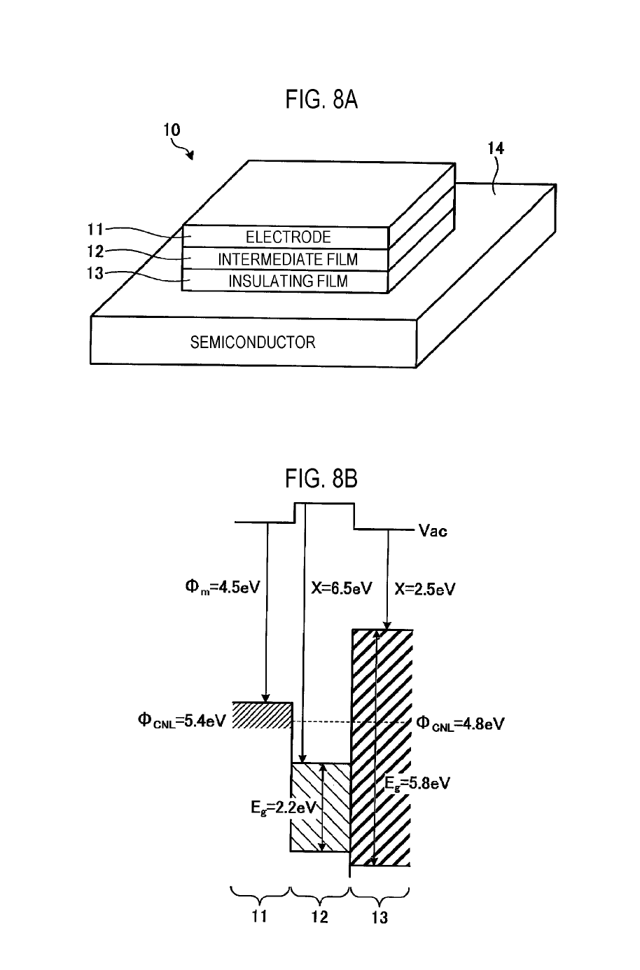

FIGS. 8A and 8B are diagrams illustrating an example of a semiconductor device 10 in the present embodiment. FIG. 8A shows an example of the structure of the semiconductor device 10 in the present embodiment. In addition, FIG. 8B shows an example of the relationship of a work function in an electrode 11, an intermediate film 12, and an insulating film 13 of the semiconductor device 10 in the present embodiment. For example, as shown in FIG. 8, the semiconductor device 10 in the present embodiment includes the electrode 11, the intermediate film 12, the insulating film 13, and a semiconductor 14. The semiconductor device 10 in the present embodiment has a Metal Insulator Semiconductor (MIS) structure.

The electrode 11 is made of a metal such as TiN, tantalum nitride (TaN) or the like. The semiconductor 14 is made of, for example, Si or the like. The insulating film 13 is provided between the electrode 11 and the semiconductor 14, and comprises an insulating transition metal oxide. The intermediate film 12 is provided between the electrode 11 and the insulating film 13. In addition, as shown in FIG. 8B, the lower end of the conduction band of the intermediate film 12 is located at a position of 6.5 eV from a vacuum potential Vac, and is lower than the Fermi level (in the example of FIG. 8B, a position of 4.5 eV from a vacuum potential Vac) of a metal (e.g., TiN or TaN) constituting the electrode 11.

In the present embodiment, the insulating film 13 may be an oxide selected from an oxide group including HfO₂, ZrO₂, Al₂O₃, Y₂O₃, CeO₂, La₂O₃, Gd₂O₃, Ta₂O₅ and Nb₂O₅, a composite oxide composed of a plurality of oxides selected from the oxide group, silicate, or a laminated film composed of a plurality of oxides selected from the oxide group. Further, the intermediate film 12 contains at least one of V₂O₅ and MoO₃.

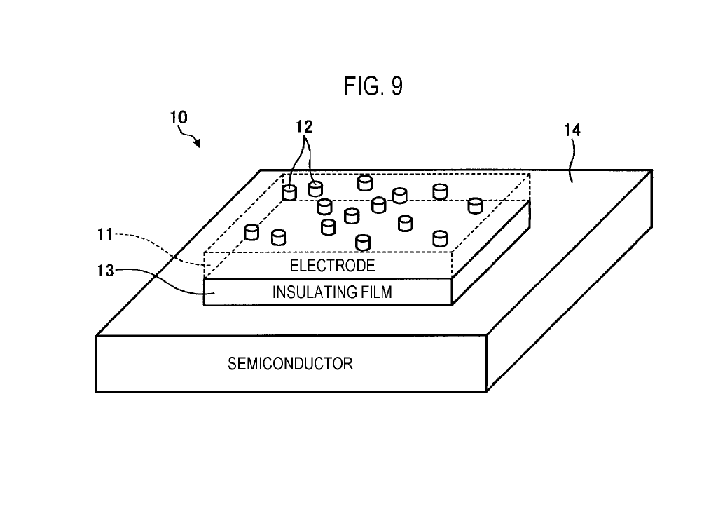

The quantum well structure may be a two-dimensional quantum well structure in which the intermediate film 12 such as granular MoO₃, V₂O₅ or the like is buried in the electrode 11, for example, as shown in FIG. 9, in addition to the thin film laminated structure shown in FIG. 8A. FIG. 9 shows another example of a semiconductor device.

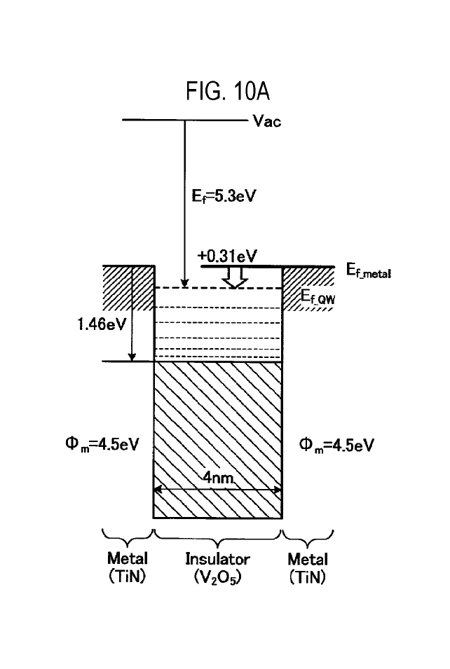

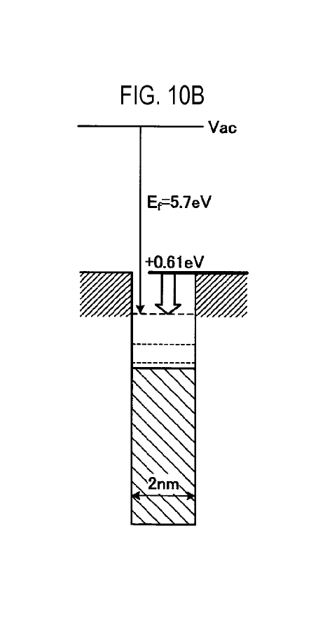

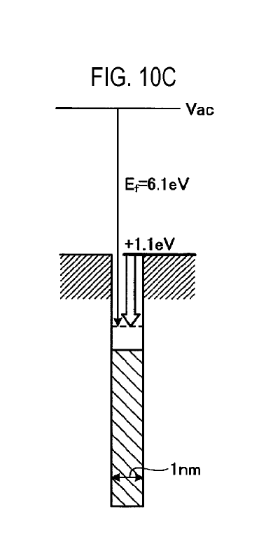

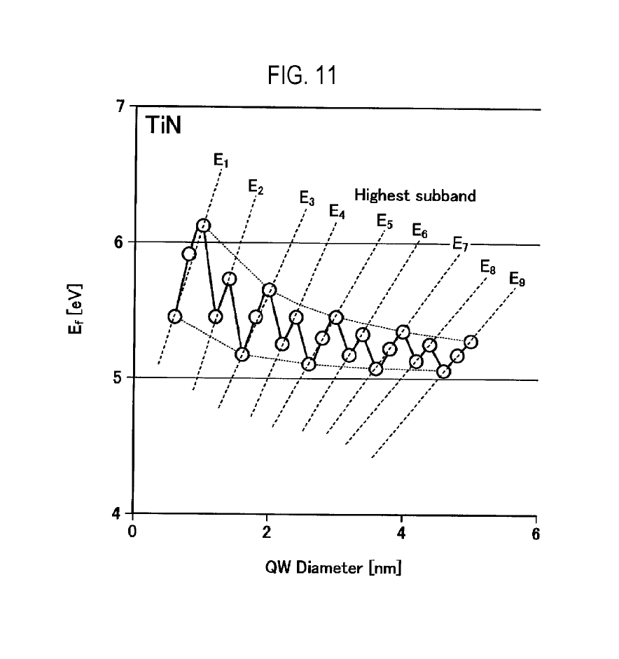

The work function of the pseudo metal electrode may be modulated by the work function of the electrode 11 adjacent to the intermediate film 12 and the film thickness of the intermediate film 12, or the diameter of the quantum well. FIGS. 10A to 10C are diagrams showing an example of adjustment of a work function according to the quantum well diameter of an insulator. FIG. 11 is a diagram showing an example of the relationship between the Fermi level and the quantum well diameter of an insulator.

For example, as shown in FIGS. 10A to 10C, when the diameter of the quantum well of the insulator is reduced, the energy of the subband rises and the Fermi level rises (the work function decreases). In addition, in the process of reducing the diameter of the quantum well of the insulator, an upper subband which determines a pseudo Fermi level sequentially transits to the lower band and eventually falls to the ground state. That is, the depth of the quantum well is determined by a difference in electron affinity between the adjacent metal electrode and an insulator such as MoO₃, V₂O₅ or the like, and the subband at the upper end of the quantum well of the metal electrode is occupied by electrons by electron injection from the adjacent metal electrode. The energy may be changed by the film thickness of the insulator such as MoO₃, V₂O₅ or the like, or the quantum well diameter.

In addition, due to a discontinuous change in the Fermi energy E_{f} accompanying the transition of the band, the pseudo Fermi level of the quantum well varies while oscillating with respect to the diameter of the quantum well, for example, as shown in FIG. 11. This is because the state of the subband occupied by electrons transits depending on the film thickness or the quantum well diameter. The value of the work function is changed discontinuously due to the transition of the state of the subband.

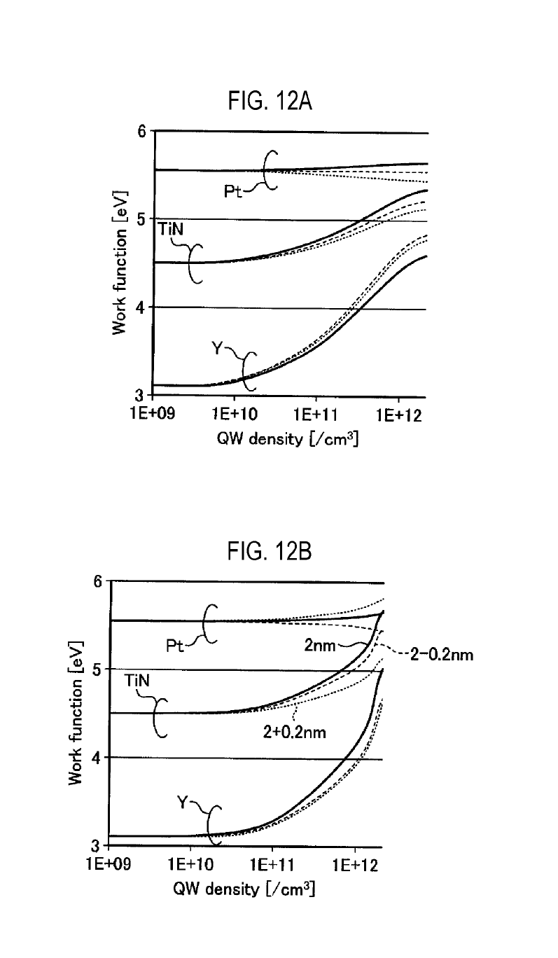

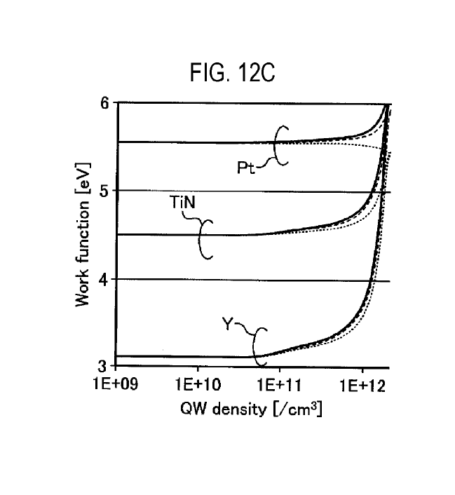

The range of the work function that can be modulated by the quantum well structure depends on the material of the metal electrode to be combined and the size and density of the quantum well. FIGS. 12A to 12C are diagrams showing an example of modulation of a work function by a material of a metal electrode and a quantum well diameter. FIG. 12A shows the modulation of a work function when the quantum well diameter of an insulator (V₂O₅) is 4±0.2 nm. FIG. 12B shows the modulation of a work function when the quantum well diameter of an insulator (V₂O₅) is 2±0.2 nm. FIG. 12C shows the modulation of a work function when the quantum well diameter of an insulator (V₂O₅) is 1±0.2 nm. For example, as can be seen from FIG. 12, a work function in a wide range can be obtained by combining with an n-type metal (for example, yttrium (Y)) having a small work function value.

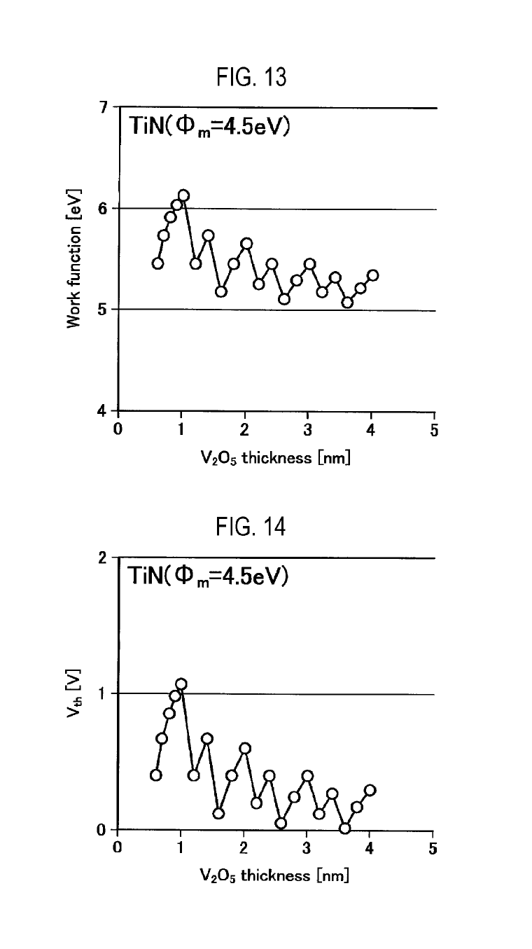

Further, as shown in FIG. 13, the work function of the intermediate film 12 varies while oscillating depending on the film thickness of the intermediate film 12. FIG. 13 is a diagram showing an example of a change in the work function of the quantum well structure with respect to the film thickness of the intermediate film 12 in the case where TiN is used as the electrode 11, V₂O₅ is used as the intermediate film 12, and HfO₂ is used as the insulating film 13. The modulation range of the work function is narrower than a metamaterial structure by a quantum well/a quantum dot (qDot).

In addition, in the range where the film thickness of the intermediate film 12 is 1 nm or less, since all the electrons in the subband fall to the ground state, there is no difference due to the material of the electrode, and the work function may be controlled only by the thickness of the intermediate film 12. That is, since the subband in the quantum well is only in the ground state by forming the quantum well with a dimension of 1 nm or less, it is possible to avoid the transition of the subband state caused by the variation in the size of the quantum well which causes the variation in the work function.

In addition, as shown in FIG. 13, when the film thickness of the intermediate film 12 is 1 nm or less, the work function varies monotonously over a wide range of 5 to 6 eV with respect to a change in film thickness. Therefore, as compared with a range where the film thickness of the intermediate film 12 is thicker than 1 nm, the control range (dynamic range) of the work function by the control of the film thickness of the intermediate film 12 may be increased. In addition, when the film thickness of the intermediate film 12 is in the range of 1 nm or less, no oscillatory change in the work function is observed with respect to the change in the film thickness. Therefore, by controlling the thickness of the intermediate film 12, the work function of the semiconductor device 10 may be precisely controlled.

In addition, for example, as shown in FIG. 14, by setting the film thickness of the intermediate film 12 to 1 nm or less, a change in the threshold voltage Vth of the semiconductor device 10 may also be suppressed. FIG. 14 is a diagram showing an example of a change in the threshold voltage Vth of the semiconductor device 10 with respect to the film thickness of the intermediate film 12 in the case where TiN is used as the electrode 11, V₂O₅ is used as the intermediate film 12, and HfO₂ is used as the insulating film 13.

Further, by forming the intermediate film 12 such as V₂O₅ by an Atomic Layer Deposition (ALD) method, the film thickness of the intermediate film 12 may be precisely controlled. This makes it possible to reduce a difference between the actual film thickness of the formed intermediate film 12 and a design target value of the film thickness of the intermediate film 12.

As described above, in the present embodiment, it is possible to control the work function of the semiconductor device 10 by controlling only the film thickness of the intermediate film 12 such as V₂O₅ or the like. Since the film thickness of the intermediate film 12 can be precisely controlled to have a value close to the design target value by the ALD method or the like, the work function may be controlled to have the value close to the design target value. As a result, it is possible to control the threshold voltage Vth of the semiconductor device 10 to a value close to the design target value.

Here, when the threshold voltage Vth of the MIS type transistor is low, an ON current of the transistor is increased and the operating speed of the transistor is improved. However, on the other hand, a leakage current between a source and a drain increases when the transistor is turned OFF.

In addition, when the threshold voltage Vth of the MIS type transistor is high, the leakage current between the source and the drain decreases when the transistor is turned OFF. However, the ON current of the transistor also decreases, and the operating speed of the transistor decreases.

As described above, there are typically two types of applications of the transistor: “high speed/high power consumption” and “low speed/low power consumption”. Therefore, it is necessary to optimize the threshold voltage Vth according to the application of the transistor.

In the present embodiment, by adopting the gate stack structure (the electrode 11, the intermediate film 12, the insulating film 13, and the semiconductor 14) shown in FIG. 8 and adjusting the film thickness of the intermediate film 12, the threshold voltage Vth of the semiconductor device 10 can be optimized.

### Leakage Current

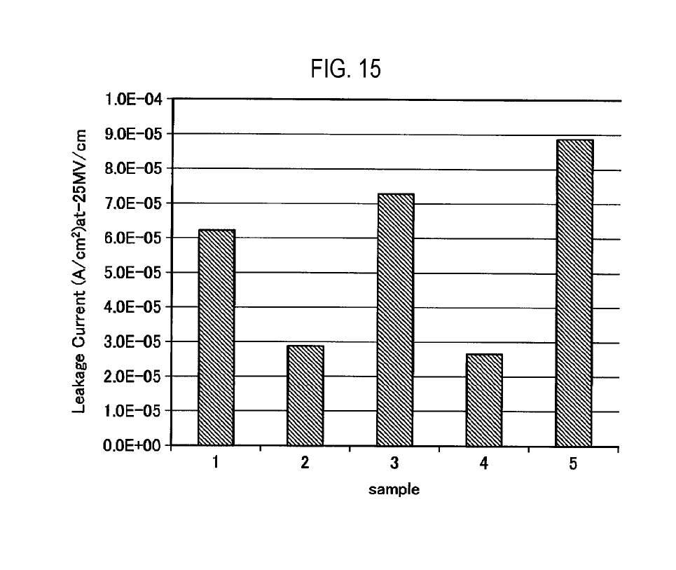

Next, the film thickness and the leakage current of the intermediate film 12 were experimented. FIG. 15 is a diagram showing an example of an experimental result of a leakage current. In the experiment shown in FIG. 15, in the semiconductor device 10 shown in FIG. 8, a sample in which the electrode 11 is provided instead of the semiconductor 14 was used. In the experiment, TiN was used as the material of the electrode 11, V₂O₅ or WO₃ was used as the material of the intermediate film 12, and ZrO₂ was used as the material of the insulating film 13. In the experiment, Sample 1 in which the intermediate film 12 was made of V₂O₅ with a film thickness of 1 to 1.5 nm, Sample 2 in which the intermediate film 12 was made of V₂O₅ with a film thickness of 1 nm or less, Sample 3 in which the intermediate film 12 was made of WO₃ with a film thickness of 1 to 1.5 nm, Sample 4 in which the intermediate film 12 was made of WO₃ with a film thickness of 1 nm or less, and Sample 5 without the intermediate film 12 were used. In all of the Samples, the film thickness of the insulating film 13 is 6 nm.

For example, as shown in FIG. 15, Samples 2 and 4 have leakage currents lower than those of other Samples by 50% or more. Samples 2 and 4 are samples each having the intermediate film 12 with a film thickness of 1 nm or less. Therefore, by setting the thickness of the intermediate film 12 to 1 nm or less, the leakage current of the semiconductor device 10 can be reduced.

Here, in the semiconductor device 10 having the structure shown in FIG. 8A, the intermediate film 12 which has the lower end of the conduction band lower than the Fermi level of the metal constituting the electrode 11 is interposed between the electrode 11 and the insulating film 13, so that the quantum well may be formed between the electrode 11 and the insulating film 13 and an apparent work function of the electrode 11 including the intermediate film 12 is increased. When the work function increases, the leakage current of the semiconductor device 10 at the time of OFF decreases, as shown in FIG. 2. Accordingly, by setting the film thickness of the intermediate film 12 to 1 nm or less, the leakage current of the semiconductor device 10 is reduced.

In the semiconductor device 10 having the structure shown in FIG. 8, when the electrode 11 is made of TiN, TiCl₄ gas and NH₃ gas are often used as source gases for TiN film formation. For example, when the intermediate film 12 is not provided, the insulating film 13 made of the transition metal oxide is exposed to corrosive and reducing atmospheres. Therefore, the insulating film 13 may be damaged and the insulation performance may deteriorate. On the other hand, in the present embodiment, the intermediate film 12 is stacked on the insulating film 13, and then the electrode 11 is laminated on the intermediate film 12. The insulating film 13 is protected from the corrosive and reducing atmosphere by the intermediate film 12. As a result, deterioration of the characteristics of the insulating film 13 can be suppressed.

### Others

For example, the structure of the semiconductor device 10 in the above-described embodiment may be applied to the gate stack structure of the p-type MOS transistor in the CMOS transistor. Specifically, the CMOS transistor may be constituted by a p-type MOS transistor having the semiconductor device 10 including the semiconductor 14 made of a p-type semiconductor as a gate stack structure and an n-type MOS transistor having a typical metal electrode, an insulating film, and an n-type semiconductor as a gate structure.

In the above embodiment, the intermediate film 12 is provided between the electrode 11 and the insulating film 13 in the semiconductor device 10 having the MIS structure, but the disclosed technique is not limited thereto. For example, in the MIM structure illustrated in FIG. 6A, the intermediate film 12 may be provided between the metal electrode and the insulator.

According to various embodiments of the present disclosure, variations in the threshold voltage Vth of the semiconductor device can be reduced, and the threshold voltage Vth can be accurately controlled.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first electrode made of a metal;
a first semiconductor;
a first insulating film configured to be provided between the first electrode and the first semiconductor and to be made of an insulating transition metal oxide; and
an intermediate film configured to be provided between the first electrode and the first insulating film,
wherein a lower end of a conduction band of the intermediate film is lower than a Fermi level of the metal constituting the first electrode.

2. The semiconductor device of claim 1, wherein a thickness of the intermediate film is 1 nm or less.

3. The semiconductor device of claim 1, wherein the insulating transition metal oxide constituting the first insulating film is an oxide selected from an oxide group consisting of hafnium oxide (HfO₂), zirconia (ZrO₂), aluminum oxide (Al₂O₃), yttrium oxide (Y₂O₃), cesium oxide (CeO₂), lanthanum oxide (La₂O₃), gadolinium oxide (Gd₂O₃), tantalum pentoxide (Ta₂O₅) and niobium pentoxide (Nb₂O₅), a complex oxide composed of a plurality of oxides selected from the oxide group, a silicate, or a laminated film composed of a plurality of oxides selected from the oxide group, and
the intermediate film contains at least one of vanadium pentoxide (V₂O₅) and molybdenum oxide (MoO₃).

4. A CMOS transistor comprising:
an n-type MOS transistor including a second electrode, a second insulating film, and a second semiconductor as a gate stack structure; and
a p-type MOS transistor including the semiconductor device of claim 1 as a gate stack structure.
